(19) United States
(12) Patent Application Publication
(10) Pub. No.: US 2013/0207136 A1
(43) Pub. Date: Aug. 15, 2013

(54) CHIP-ON-BOARD LEDS PACKAGE WITH DIFFERENT WAVELENGTHS

(71) Applicants: Hsin-Hui Cheng, New Taipei City (TW); Chao-Kuei Chan, Zhunan Township (TW)

(72) Inventors: Hsin-Hui Cheng, New Taipei City (TW); Chao-Kuei Chan, Zhunan Township (TW)

(21) Appl. No.: 13/372,052

(22) Filed: Feb. 13, 2012

(51) Int. Cl. H01L 33/08

(52) U.S. Cl. 257/89; 257/E33.073

(57) ABSTRACT

A chip-on-board LEDs package with different wavelengths is provided. The substrate has a conductive layer to connect LEDs with different wavelengths, color temperatures and packages. Therefore, the LEDs could be formed an illuminant matrix with different types connected thereof. Also, a lens is disposed on the illuminant matrix to protect the chip-on-board LEDs structure and enhance luminous efficiency.

### BACKGROUND OF THE INVENTION

1. Field of the Invention

The present invention relates to a package structure, and more particularly but not by any way of limitation, to a chip-on board LEDS package with different wavelengths, color temperatures and package types for plant growth, agricultural use, and cultivating fish.

2. Related Art

For decades scientists have delved ever deeper into the inner workings of plants, and particularly into those processes which are driven by the chemical capture of light energy. At the same time, research into new methods for converting electricity into light of particular wavelengths has led some engineers to try to produce artificial lighting which promotes plant growth. Until recently this has meant modifying energy inefficient “white light” sources to produce more light at wavelengths known to promote plant growth and health. This hybrid technology, in which the bulk of the light from these augmented “plant grow lights” can't be used efficiently by plants, has dominated the market for four decades.

While electricity was abundant and cheap, these “old school” plant grow lights, based mainly on HID, high pressure sodium, or fluorescent style lamps, were acceptable despite their imperfections. But they still have many shortcomings. They typically convert only 10-15% of electrical energy into light, and only a very small portion of that light can be used by plants. Some of them, particularly the HID lamps, emit short wavelength UV light which is damaging to both the plants being grown under them and the people tending the plants. All of these lamps generate waste heat which must be eliminated to prevent damage to the plants they illuminate, adding to their operational cost. They contain environmentally damaging metals, are fragile, and have a short operating life.

As electricity supplies fail to keep pace with demand, leading to ever higher prices, the need for more efficient plant growing lights increases. The latest generation of high output LEDs, with their narrow light output wavelengths, are a good choice for creating the next generation of plant grow lighting. Most LED plant grow lighting systems available today can only be used in a laboratory. The others, while claiming to be useful to commercial plant growers, are merely modifications of the laboratory-specific systems.

To our knowledge, no one has yet developed an efficient LED-based plant growing light that is amenable to both home lighting design and commercial plant production. By designing our LED lamp as a bulb, which can be used in industry standard lighting fixtures, we have created a product that has universal appeal and marketability. Our lamp can be manufactured inexpensively with readily available parts for both home and commercial use.

### SUMMARY OF THE INVENTION

To solve the aforementioned problems of the prior art, the present invention provides a chip-on board LEDS package to integrate LED chip with different wavelengths, color temperatures and package types to form an illuminant matrix for plant growth, agricultural use, and cultivating fish.

Accordingly, the present invention discloses a COB LEDS package including a substrate, a conductive layer, a plurality of LED chips and at least one lens. The conductive layer is disposed on the substrate, and is divided into a plurality of conductive areas. The LED chips with different wavelengths are disposed on the conductive layer. The LED chips have at least one package type and electrically connect to at least one of the conductive area to form an illuminant matrix. The lenses are disposed on the substrate to cover and protect the LED chips.

These and other features, aspects, and advantages of the present invention will become better understood with reference to the following description and appended claims. It is to be understood that both the foregoing general description and the following detailed description are examples, and are intended to provide further explanation of the invention as claimed.

### BRIEF DESCRIPTION OF THE DRAWINGS

The present invention will become more fully understood from the detailed description given herein for illustration only, and thus is not limitative of the present invention, and wherein:

FIG. 1A is a respective view of an embodiment of the illuminant matrix of a chip-on board LEDS package in accordance with the present invention;

FIG. 1B is a respective view of another embodiment of the illuminant matrix of a chip-on board LEDS package in accordance with the present invention;

FIG. 1C is a respective view of another embodiment of the illuminant matrix of a chip-on board LEDS package in accordance with the present invention;

FIG. 2A is a cross-sectional view of an embodiment of a chip-on board LEDS package in accordance with the present invention;

FIG. 2B-2G are cross-sectional views of another embodiment of a chip-on board LEDS package in accordance with the present invention;

FIG. 3A is a respective view of an embodiment of the lens of a chip-on board LEDS package in accordance with the present invention;

FIG. 3B is a respective view of another embodiment of the lens of a chip-on board LEDS package in accordance with the present invention;

FIG. 3C is a top view of another embodiment of the lens of a chip-on board LEDS package in accordance with the present invention;

FIG. 4A is a respective view of an embodiment of the flat lens of a chip-on board LEDS package in accordance with the present invention;

FIG. 4B is a respective view of another embodiment of the flat lens of a chip-on board LEDS package in accordance with the present invention;

FIG. 4C is a top view of another embodiment of the flat lens of a chip-on board LEDS package in accordance with the present invention;

FIG. 5A is a respective view of an embodiment of the optical lens of a chip-on board LEDS package in accordance with the present invention;

FIG. 5B is a respective view of another embodiment of the optical lens of a chip-on board LEDS package in accordance with the present invention; and

FIG. 5C is a top view of another embodiment of the optical lens of a chip-on board LEDS package in accordance with the present invention.

### DETAILED DESCRIPTION OF THE INVENTION

Reference will now be made in detail to the present preferred embodiments of the invention, examples of which are illustrated in the accompanying drawings. Wherever possible, the same reference numbers are used in the drawings and the description refers to the same or the like parts.

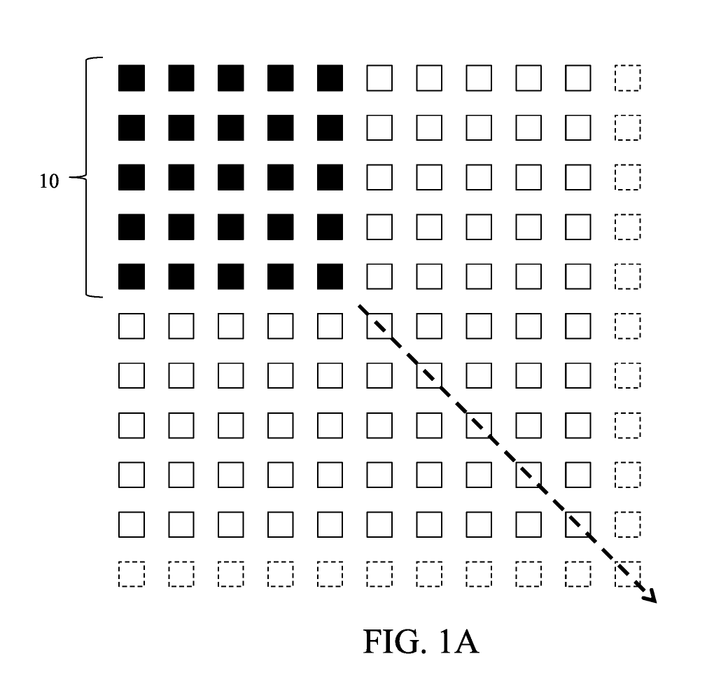

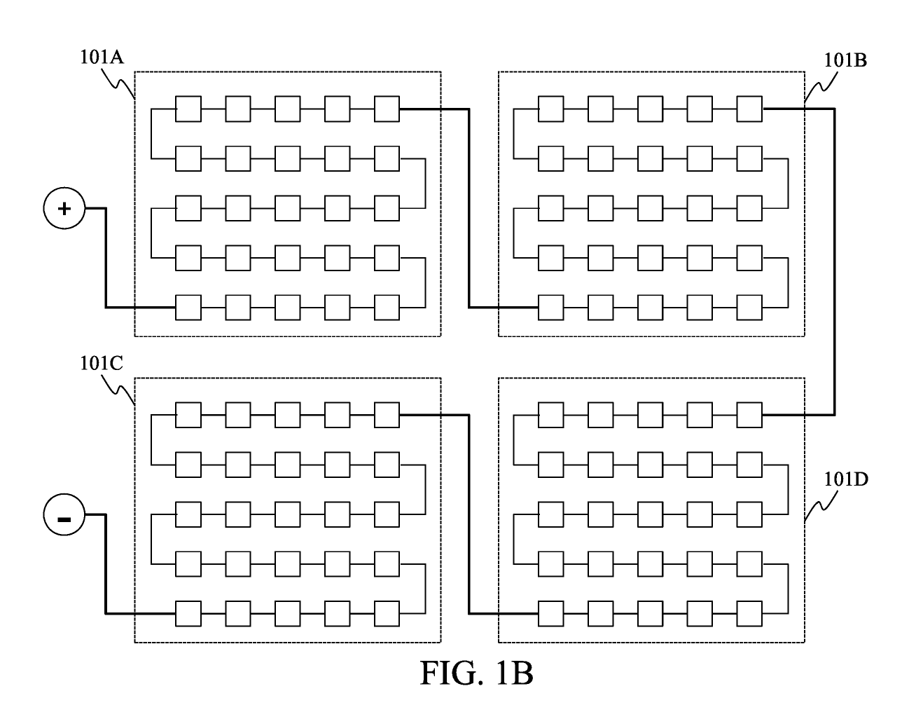

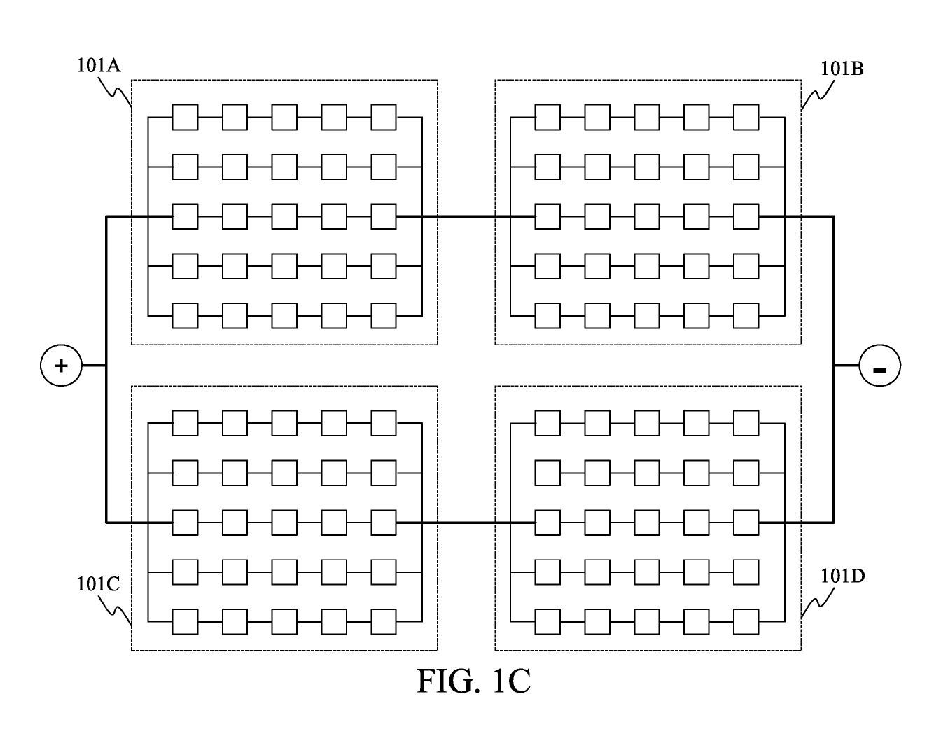

Please refer to FIG. 1A, which is a respective view of the illuminant matrix of a chip-on board LEDS package in accordance with the present invention.

The COB (chip-on board) LEDS package of the invention includes a substrate with a conductive layer thereon. When the substrate is made of conductive materials, an insulating layer has to be added between the substrate and the conductive layer. A plurality of LED chips are disposed on the conductive layer to form an illuminant matrix 10. The number of the LED chips is not limited, and each LED chip is connected by parallel connection, serial connection or a combination thereof. The LED chip may be selected from a red light LED chip with wavelength 620 to 670 nm, a infrared light LED chip with wavelength 700 to 750 nm, blue light LED chip with wavelength 390 to 460 nm, an ultra-violet light LED chip with wavelength 280 to 320 nm, a green light LED chip with wavelength 500 to 580 nm, a yellow light LED chip with wavelength 580 to 600 nm, a LED chip with color temperature of about 2600K to 10000K and a combination thereof.

The forward bias voltages of the LED chips with different wavelength and color temperature are also different. Therefore, the illuminant matrix 10 is defined as at least one working area. The difference in a forward bias voltage between the adjacent LED chips of each working area is less than 5% to increase the stability during operation. The working areas are electrically connected by parallel connection, serial connection or a combination thereof to be controlled together or each working area could be controlled independently.

For example, please refer to FIG. 1B, the illuminant matrix is defined as four 5*5 working areas 101A, 101B, 101C and 101D. All the LED chips are electrically connected by serial connection within the working areas 101A, 101B, 101C and 101D. And the working areas 101A, 101B, 101C and 101D are also electrically connected by serial connection. Please refer to FIG. 1C, five LED chips are connected by serial connection in each row. Then all the rows are connected by parallel connection. The working areas 101A, 101B are connected by serial connection. The working areas 101C, 101D are connected by serial connection. Then they are connected together by parallel connection.

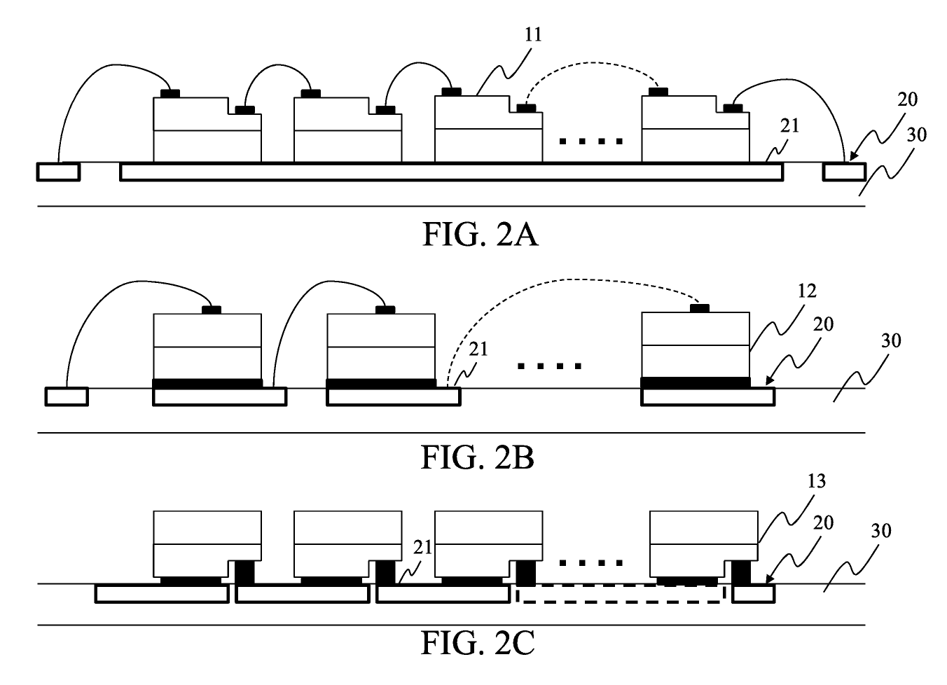

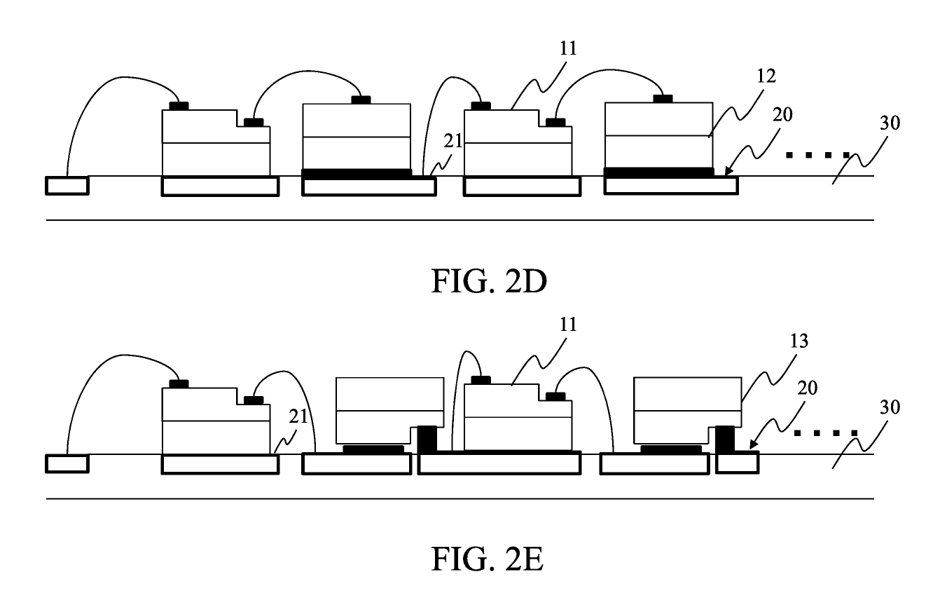

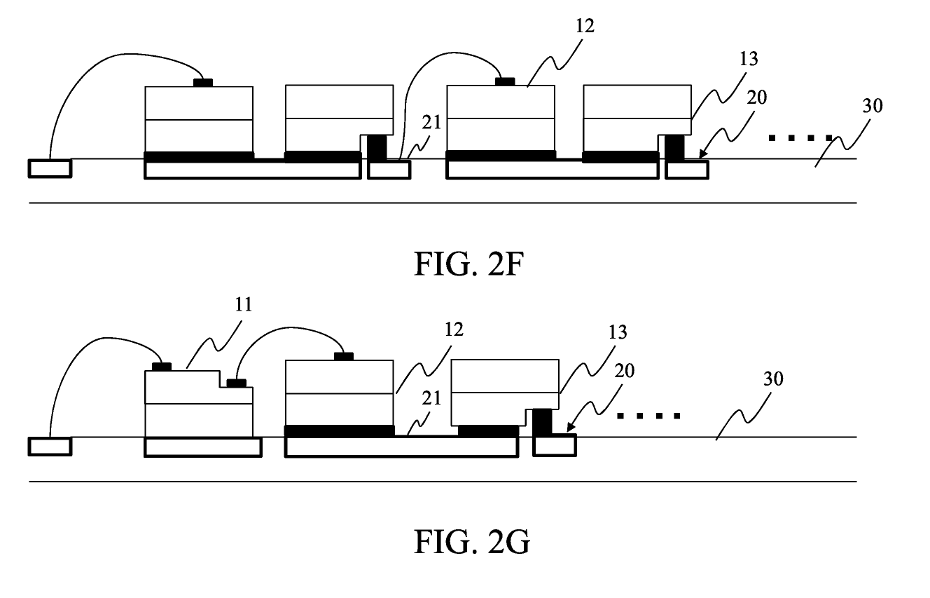

Please refer to FIG. 2A, which is a cross-sectional view of an embodiment of the illuminant matrix of a chip-on board LEDS package in accordance with the present invention.

The LED chips 11 of this embodiment are horizontal type, such as Horizontal PN chip, with different wavelength and color temperature. The electrodes are located on the top surface of the horizontal type LED chips 11. The wire bonding is utilized to connect to the adjacent LED chips 11 the conductive layer 20 to form the serial connection.

Excepting for the horizontal type, the LED chips 12 may be vertical type, such as Vertical PN chip, with different wavelength and color temperature, refer to FIG. 2B. The two electrodes are located on the top surface and the bottom surface respectively. The wire bonding is utilized to connect to the adjacent LED chips 12 the conductive layer 20 to form the serial connection for the electrode on the top surface. The electrode on the bottom surface is electrically connected when disposed on the conductive layer 20.

Please see FIG. 2C, the LED chips 13 of this embodiment are flip chip type with different wavelength and color temperature. The electrodes are located on the bottom surface of the horizontal type LED chips 13. The electrodes on the bottom surface are electrically connected when disposed on the conductive layer 20 to form the serial connection.

For the above basic package type of the LED chips, all the three package types of the LED chips can be disposed individually on the package structure of this invention due to the conductive layer 20 is divided into a plurality of conductive areas 21. Moreover, the package structure of this invention can also combine more than one type LED chip, please see FIGS. 2D-2G.

In FIG. 2D, the horizontal type LED chips 11 and the vertical type LED chips 12 are included. In FIG. 2E, the horizontal type LED chips 11 and the flip chip type LED chips 13 are included. In FIG. 2F, the vertical type LED chips 12 and the flip chip type LED chips 13 are included. And for FIG. 2G, all the three types of LED chips 11, 12, 13 are included. Due to the conductive layer 20 is divided into a plurality of conductive areas 21, all package type of LED chips 11, 12, 13 can properly electrically connected on the conductive areas 21 without shorting.

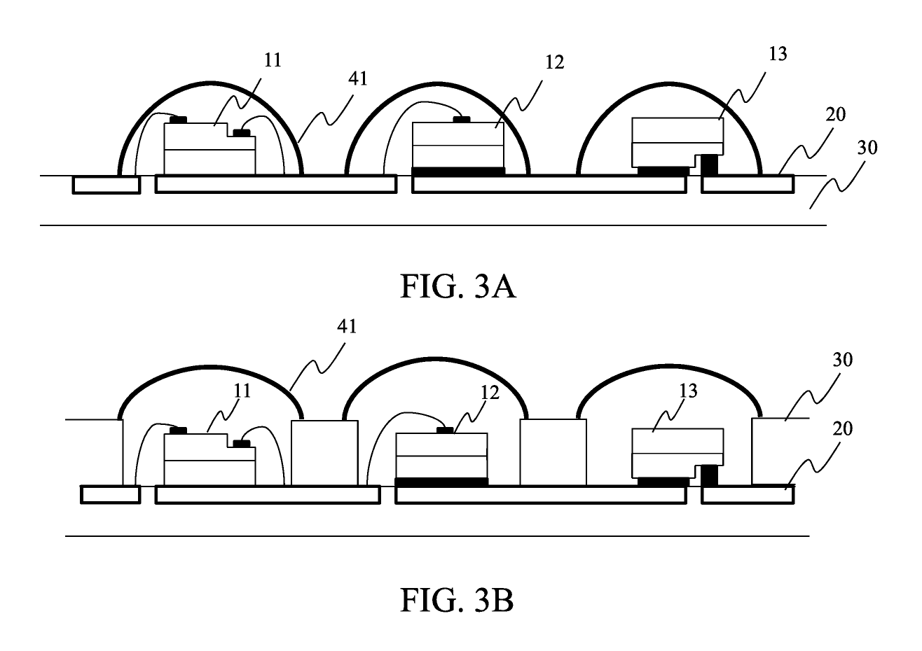

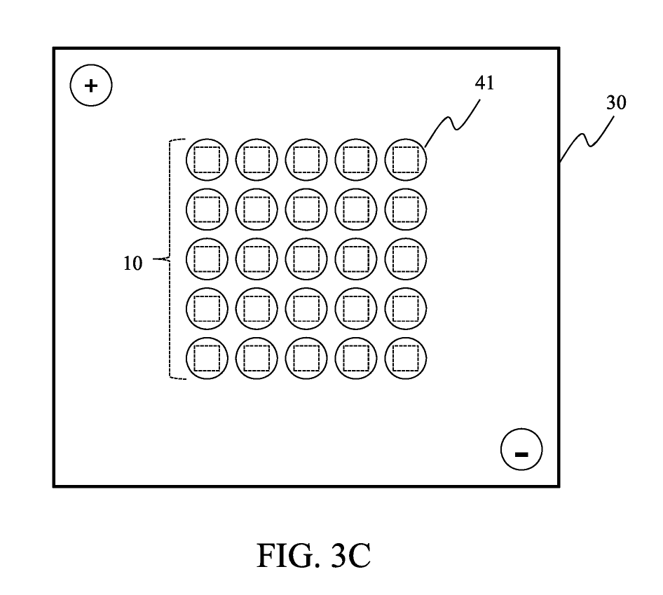

Please refer to FIG. 3A, which is a respective view of the lens of a chip-on board LEDS package in accordance with the present invention.

After the LED chips 11, 12, 13 are disposed, the lens 41 are also disposed on the substrate 30 to cover each LED chips 11, 12, 13 respectively. The lens 41 is used to cover and protect the LED chips 11, 12, 13, the conductive area 21, also see FIG. 3C. Also, the lens 41 can improve the luminous efficiency. Please refer to FIG. 3B, the substrate 30 has sidewalls between the LED chips 11, 12, 13 to enhance the structure strength. The material of the substrate 30 is metal, such as aluminum, copper, ceramic, silicone, diamond, or graphite.

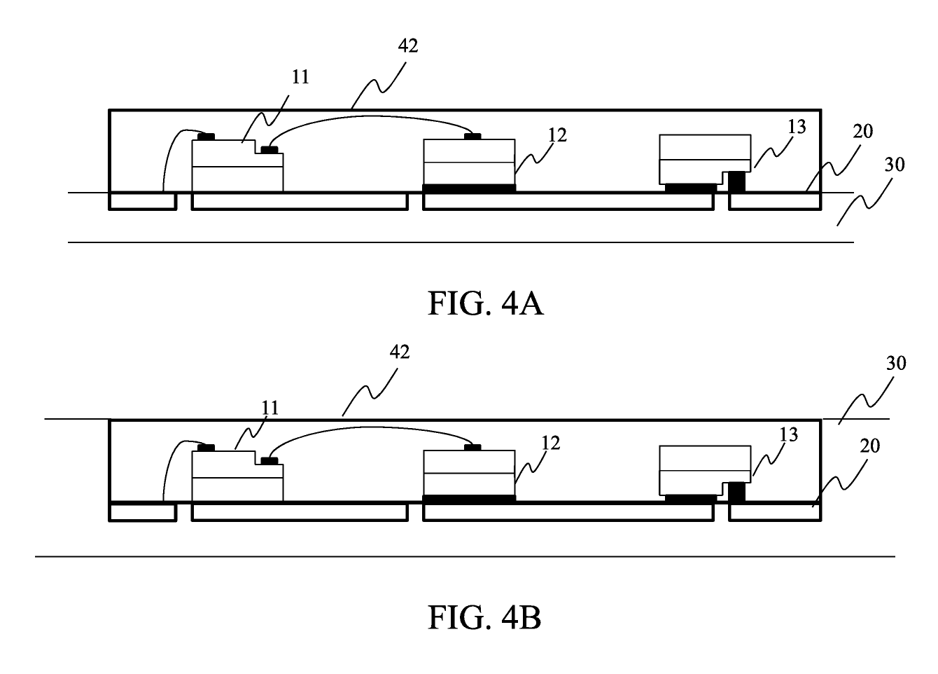

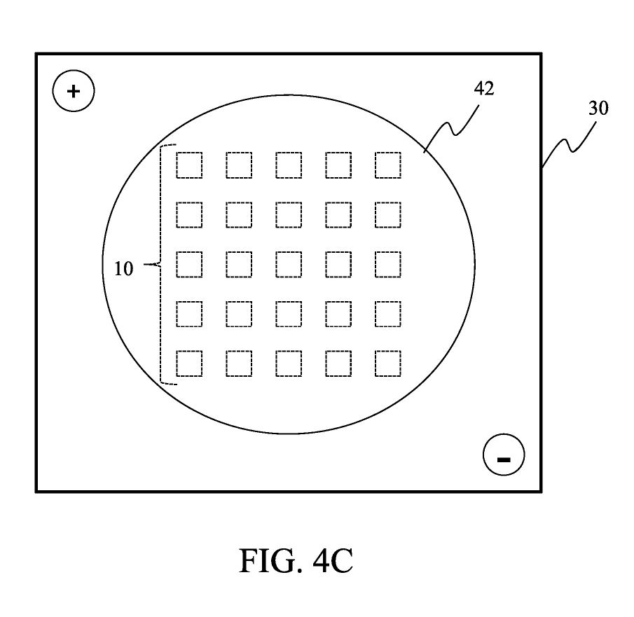

Excepting for the individual lens 41, a flat lens 42 can be used to cover at least one LED chips 11, 12, 13, please see FIGS. 4A, 4C. Also, for improving the structure strength, the sidewalls of the substrate 30 may also be used, see FIG. 4B.

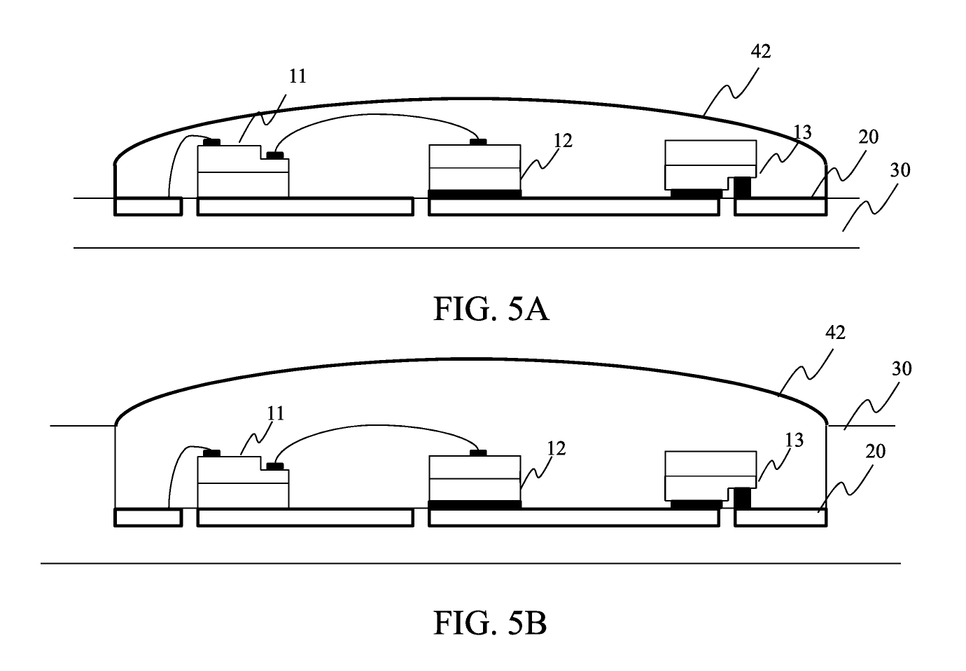

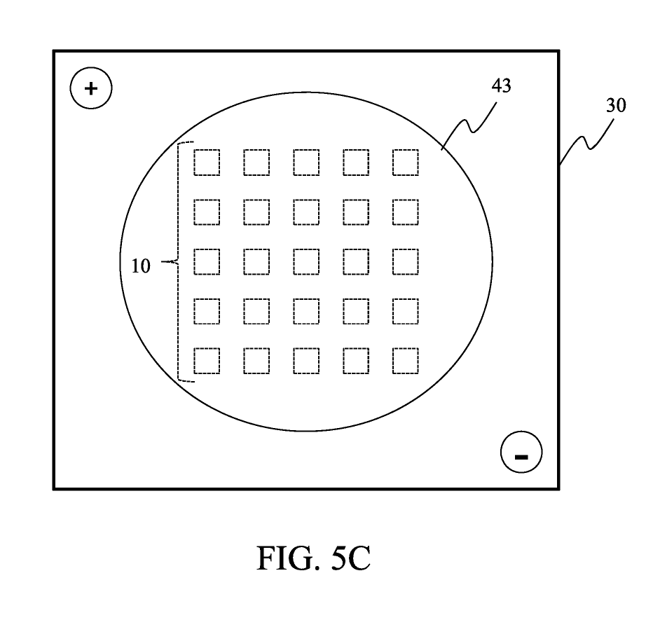

Please refer to FIGS. 5A-5C, the flat lens 42 can be replaced to an optical lens 43 to improve the luminous efficiency. The sidewalls of the substrate 30 may also be used, see FIG. 5B. The material of the lens 41, 42, 43 may be silicone, Epoxy or glass.

While an illustrative and presently preferred embodiment of the invention has been described in detail herein, it is to be understood that the inventive concepts may be otherwise variously embodied and employed and that the appended claims are intended to be construed to include such variations except insofar as limited by the prior art.

What is claimed is:

1. A chip-on-board LEDS (light emitting diode ; LED) package with different wavelengths, comprising:
a substrate;
a conductive layer, disposed on the substrate, the conductive layer is divided into a plurality of conductive areas;
a plurality of LED chips with different wavelengths, disposed on the conductive layer, the LED chips have at least one package type and electrically connect to at least one of the conductive area to form an illuminant matrix; and
at least one lens, disposed on the substrate and covering the LED chips.

2. The chip-on-board LEDS package with different wavelengths of claim 1, wherein the substrate is formed of material including metal, ceramic, silicone, diamond, or graphite.

3. The chip-on-board LEDS package with different wavelengths of claim 1, wherein the illuminant matrix include at least one of a red light LED chip, a infrared light LED chip, blue light LED chip, an ultra-violet light LED chip, a green light LED chip, a yellow light LED chip and a combination thereof.

4. The chip-on-board LEDS package with different wavelengths of claim 1, wherein the LED chips have a color temperature of about 2600K to 10000K.

5. The chip-on-board LEDS package with different wavelengths of claim 1, wherein the package type of the LED chips includes horizontal type, vertical type and flip chip type.

6. The chip-on-board LEDS package with different wavelengths of claim 1, wherein a material of the lens is silicone, glass or Epoxy.

7. The chip-on-board LEDS package with different wavelengths of claim 1, wherein the illuminant matrix includes at least one working area, each working area has the LED chips, the LED chips are electrically connected by parallel connection, serial connection or a combination thereof.

8. The chip-on-board LEDS package with different wavelengths of claim 7, wherein a difference in a forward bias voltage between the adjacent LED chips of each working area is less than 5%.

9. The chip-on-board LEDS package with different wavelengths of claim 7, wherein the working areas are electrically connected by parallel connection, serial connection or a combination thereof.
